(19) United States
(12) Patent Application Publication
(10) Pub. No.: US 2013/0314877 A1
(43) Pub. Date: Nov. 28, 2013

(54) SEMICONDUCTOR PACKAGE AND WIRING BOARD UNIT

(71) Applicant: FUJITSU LIMITED, Kawasaki-shi (JP)

(72) Inventors: Manabu WATANABE, Yokohama (JP); Kenji FUKUZONO, Kawasaki (JP)

(73) Assignee: FUJITSU LIMITED, Kawasaki-shi (JP)

(21) Appl. No.: 13/849,792

(22) Filed: Mar. 25, 2013

(30) Foreign Application Priority Data
May 28, 2012 (JP) 2012-120686

(51) Int. Cl. H01L 23/34; H05K 1/02

(52) U.S. Cl. CPC H01L 23/34; H05K 1/0203
USPC 361/719; 257/687

(57) ABSTRACT

A semiconductor package includes: a package substrate; a semiconductor chip mounted on the package substrate; a heat conductor that has a body section joined to the semiconductor chip via a metal joining material and a leg section that surrounds the semiconductor chip, the leg section extending from the body section to the package substrate and having an end bonded to the package substrate; and stress reducing members configured to reduce stress exerted on the metal joining material located on the semiconductor chip, the stress reducing members being disposed on the package substrate at positions corresponding to corners of the semiconductor chip inside the leg section and joined to the package substrate and the body section.

### CROSS-REFERENCE TO RELATED APPLICATION

This application is based upon and claims the benefit of priority of the prior Japanese Patent Application No. 2012-120686, filed on May 28, 2012, the entire contents of which are incorporated herein by reference.

### FIELD

The embodiments discussed herein are related to a semiconductor package and a wiring board unit.

### BACKGROUND

In recent years, as the central processing unit (CPU) etc. in electronic devices attain higher functionality and speed, the quantity of heat generated in semiconductor chips tends to increase. A semiconductor chip is rarely mounted directly on a large system board, but is typically mounted on a small substrate called a package substrate. A package substrate having a semiconductor chip mounted thereon is called a semiconductor package. This semiconductor package is mounted on a printed wiring board called a system board or motherboard, for example.

When the semiconductor package is mounted on the printed wiring board in the above manner, a heat sink or other heat dissipating mechanism is mounted above the semiconductor package to dissipate heat from the semiconductor chip to the atmosphere. A heat spreader or other heat conductor is provided in contact with a surface of the semiconductor chip on the semiconductor package. As described above, there have been proposed technologies that efficiently transfer heat from the semiconductor chip to the heat sink by disposing a heat conductor between the semiconductor chip and the heat sink. The heat conductor has a leg section extending toward the package substrate. An end of the leg section of the heat conductor is bonded to the package substrate with an adhesive made of resin or the like.

In the above semiconductor package, the heat conductor is sometimes joined to the semiconductor chip with a joining material. Solder or other metal joining material, for example, is used as the joining material to join the heat conductor to the semiconductor chip.

When a metal joining material is used as the joining material to join the heat conductor placed on the semiconductor chip to the semiconductor chip as described above, the metal joining material is heated and melted in the stage in which the heat conductor is mounted on the package substrate. When the semiconductor package is heated to join the heat conductor to the semiconductor chip, the package substrate and the heat conductor expand while the metal joining material is melted. Then, in the subsequent stage in which heat is removed, the package substrate and heat conductor shrink while the metal joining material is solidified.

Since the package substrate and the heat conductor have different coefficients of thermal expansion, their amounts of shrinkage during the heat removal stage are also different. Consequently, stress is concentrated on the solidified metal joining material and possibly damages the metal joining material. Furthermore, after the semiconductor package is incorporated in an electronic device, the temperature of the semiconductor chip fluctuates as the semiconductor chip heats and then ceases to heat each time the electronic device is turned on and off. It is concerned that this additional stress applied to the above metal joint may possibly damage the metal joint.

The following are reference documents:

[Document 1] Japanese Laid-open Patent Publication No. 2010-50274 and

[Document 2] Japanese Laid-open Patent Publication No. 10-303340.

### SUMMARY

According to an aspect of the invention, a semiconductor package includes: a package substrate; a semiconductor chip mounted on the package substrate; a heat conductor that has a body section joined to the semiconductor chip via a metal joining material and a leg section that surrounds the semiconductor chip, the leg section extending from the body section to the package substrate and having an end bonded to the package substrate; and stress reducing members configured to reduce stress exerted on the metal joining material located on the semiconductor chip, the stress reducing members being disposed on the package substrate at positions corresponding to corners of the semiconductor chip inside the leg section and joined to the package substrate and the body section.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view of a wiring board unit according to an embodiment;

FIG. 2 is a top view of the wiring board unit according to the embodiment;

FIG. 3 is a perspective view of a heat spreader according to the embodiment, as viewed from below;

FIG. 4 is a side view of a stress reducing member according to the embodiment;

FIG. 5 illustrates the plan-view positioning of the stress reducing members according to the embodiment;

FIG. 6 is a partial cross-sectional view of a semiconductor package according to another embodiment;

FIG. 7 is a view illustrating cracks in a metal joining material in a conventional semiconductor package; and

FIG. 8 is a plan view illustrating the shape and dimensions of the semiconductor package according to an embodiment used for verification.

### DESCRIPTION OF EMBODIMENTS

Hereinafter, a semiconductor package and a wiring board unit according to embodiments will be described in detail by way of example with reference to the drawings.

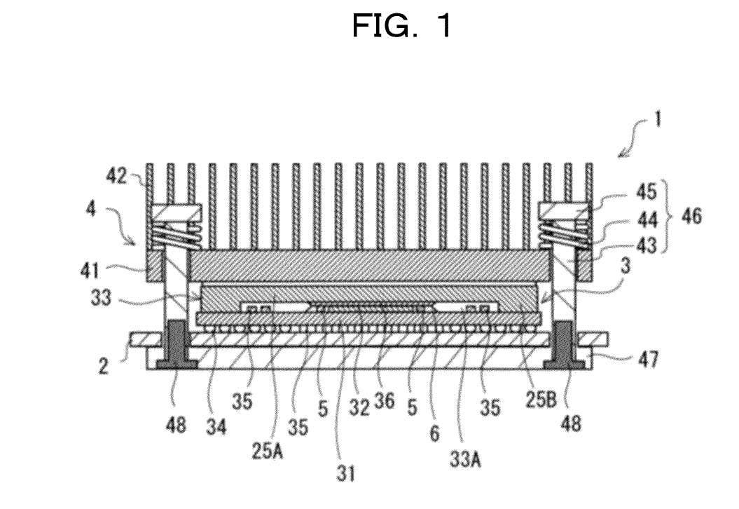

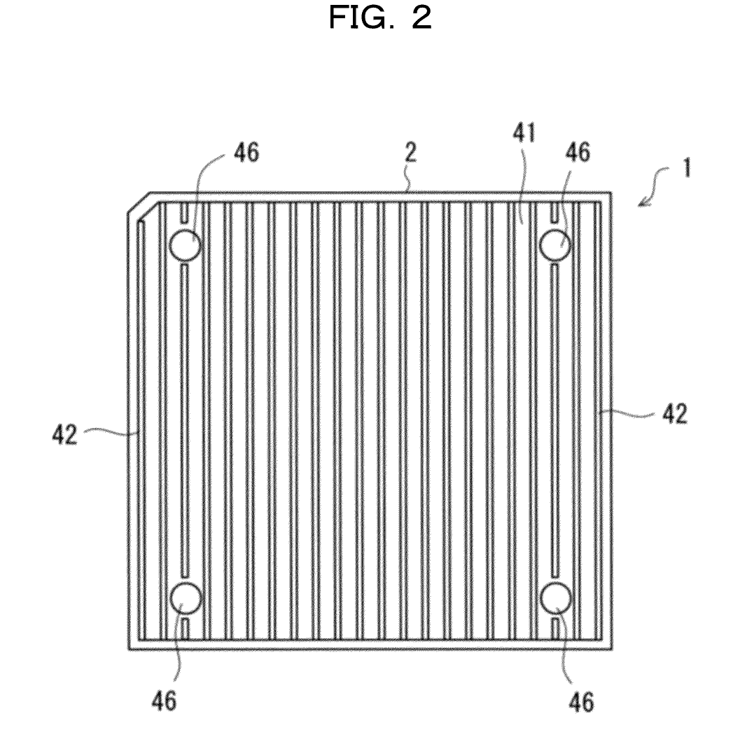

FIG. 1 is a cross-sectional view of a wiring board unit 1 according to an embodiment. FIG. 2 is a top view of the wiring board unit 1 according to the embodiment. The wiring board unit 1 includes a main board 2 that is a printed wiring board. A resin substrate, for example, is used as the main board 2. An LSI, CPU, or other semiconductor package 3 is mounted on the main board 2 using a ball grid array (BGA) packaging technique, for example.

The semiconductor package 3 includes a package substrate 31 formed from a resin substrate, a semiconductor chip 32 mounted on the package substrate 31, and a heat spreader 33, for example. The package substrate 31 has a generally rectangular contour and is formed from a glass epoxy multilayer substrate, for example. A plurality of bumps 34 are provided on the lower surface (rear surface) of the package substrate 31. The semiconductor package 3 is electrically connected to the upper surface (top surface) of the main board 2 via the bumps 34. Solder balls, for example, may be used as the bumps 34. Lead-free solder made of an alloy of tin, silver, or copper, for example, may preferably be used for the solder balls.

In addition to the semiconductor chip 32, chip components 35 such as chip capacitors and chip resistors, for example, are mounted on the upper surface (top surface) of the package substrate 31. Chip components 35 are also surface-mounted on the lower surface (rear surface) of the package substrate 31. The semiconductor chip 32 and chip components 35 are electrically connected to terminals of the package substrate 31 by flip chip connection, for example.

The heat spreader 33 serves both as the lid for sealing the semiconductor chip 32 and as the heat conducting member. A heat sink 4 as the heat dissipating member (cooling member) is provided above the heat spreader 33 to transfer heat from the semiconductor chip 32 to the heat sink 4 via the heat spreader 33 and a metal joining material described later.

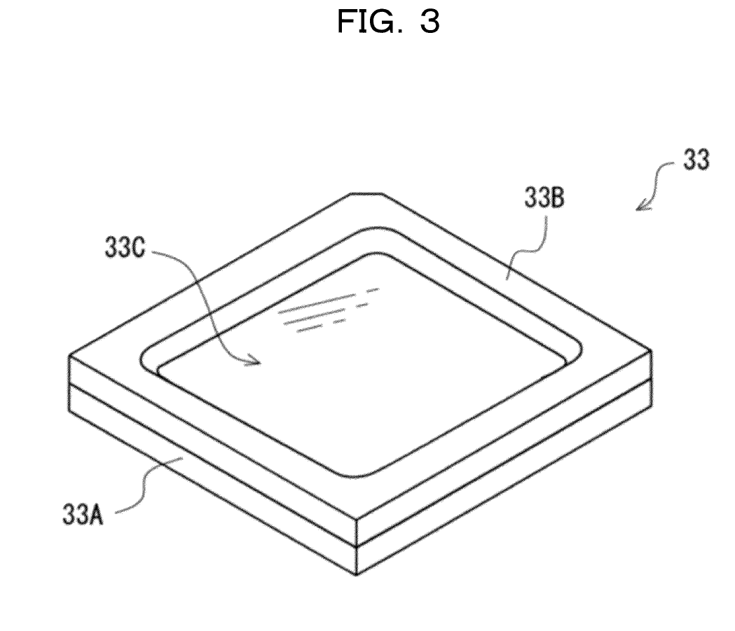

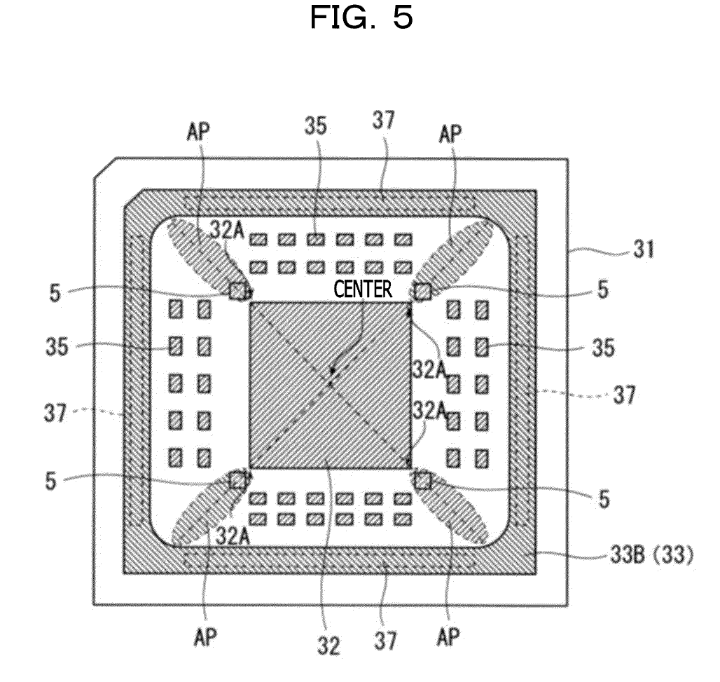

FIG. 3 is a perspective view of the heat spreader 33 according to the embodiment as viewed from below. The heat spreader 33 has a body section 33A positioned above the semiconductor chip 32, a leg section 33B extending downward (drooping) from the body section 33A to the package substrate 31, and an accommodation recess 33C configured to accommodate the semiconductor chip 32 therein. The end surface of the leg section 33B is bonded (joined) to the package substrate 31 via a thermosetting resin adhesive (indicated by reference numeral 37 in FIG. 5). The adhesive used to bond the leg section 33B of the heat spreader 33 to the upper surface (front surface) of the package substrate 31 is not limited to the thermosetting resin adhesive, but various adhesives may be employed. The leg section 33B defines a rectangular opening such that the semiconductor chip 32 mounted on the package substrate 31 is surrounded by the leg section 33B.

In the present embodiment, the accommodation recess 33C of the heat spreader 33 is formed in a box-like shape defining an accommodation space surrounded by the lower surface of the body section 33A, inner surface of the leg section 33B, and the upper surface (top surface) of the package substrate 31. The accommodation recess 33C is not limited to the box-like shape, but may have another shape. The heat spreader 33 may be formed from copper, aluminum, or other metal material having excellent heat conductivity (thermal conductance), for example. The heat spreader 33 is an example of heat conductor.

The body section 33A of the heat spreader 33 mainly serves to transfer heat from the semiconductor chip 32 to the heat sink 4. The body section 33A has a contour larger than the upper surface of the semiconductor chip 32, so it transfers heat from the semiconductor chip 32 to the heat sink 4 while distributing the heat along the surface of the body section 33A. In the semiconductor package 3 according to the present embodiment, the upper surface of the semiconductor chip 32 is thermally connected to the lower surface (rear surface) of the body section 33A of the heat spreader 33 via a metal joining material 36 having a low thermal resistance. This improves heat conductivity from the semiconductor chip 32 to the heat spreader 33. In the present embodiment, solder is used as an example of metal joining material 36, but the metal joining material 36 is not limited thereto. Indium-based solder (such as In, In-3Ag, or In-10Ag), for example, may be used suitably as the solder used for the metal joining material 36, but another solder may be used instead.

The heat sink 4 has a base plate 41 and a plurality of heat dissipating fins 42. The base plate 41 is a plate-shaped member mounted above the body section 33A of the heat spreader 33 and extending along the surface of the main board 2. The base plate 41 has a contour extending outward beyond the periphery of the body section 33A. A thermally conductive sheet or other thermally conductive material is provided between the body section 33A of the heat spreader 33 and the base plate 41 to allow them to be in thermal contact with each other. The heat dissipating fins 42 are thin heat dissipating plates fastened to the base plate 41. Each heat dissipating fin 42 is vertically erected upward from the upper surface of the base plate 41. The heat dissipating fins 42 are arranged in parallel to each other defining air passages extending in the same direction between adjacent heat dissipating fins 42. Aluminum, copper, or other metal material, for example, may be used for the base plate 41, heat dissipating fin 42, etc.

The heat sink 4 is secured to the main board 2 by fastening members 46 including bolts 43, springs 44, and nuts 45. As illustrated in FIG. 2, the fastening members 46 are positioned at the four corners of the base plate 41 of the heat sink 4. More specifically, the base plate 41 has through holes at the four corners thereof to receive the bolts 43. Each bolt 43 is connected at one end thereof to a bolster plate 47 provided on the rear surface of the main board 2 via a driving screw or other fixture 48. The other end of the bolt 43 is fitted with a nut 45 and a spring 44, such that, when tightened, the nut 45 compresses the spring 44. The restoring force of the spring 44 presses the base plate 41 against the heat spreader 33 and thereby strongly secures the heat sink 4 and semiconductor package 3 to the main board 2. More specifically, the fastening members 46 serve both to fasten the heat sink 4 to the main board 2 and to fasten the semiconductor package 3 to the main board 2.

As described above, the semiconductor chip 32 and heat spreader 33 are joined to each other via the metal joining material 36 having excellent thermal conductivity, while the heat spreader 33 is in thermal contact with the base plate 41 of the heat sink 4. Heat generated in the semiconductor chip 32 in operation is accordingly transferred to the heat sink 4 via the metal joining material 36 and the body section 33A of the heat spreader 33 and is dissipated by the heat dissipating fins 42 to the atmosphere. Although the air-cooling type heat sink 4 is adopted as an exemplary cooling member to cool the semiconductor package 3 in the present embodiment, another mechanism may be employed. A liquid-cooling type cooling mechanism having channels formed in the base plate 41 to circulate a coolant may be used instead.

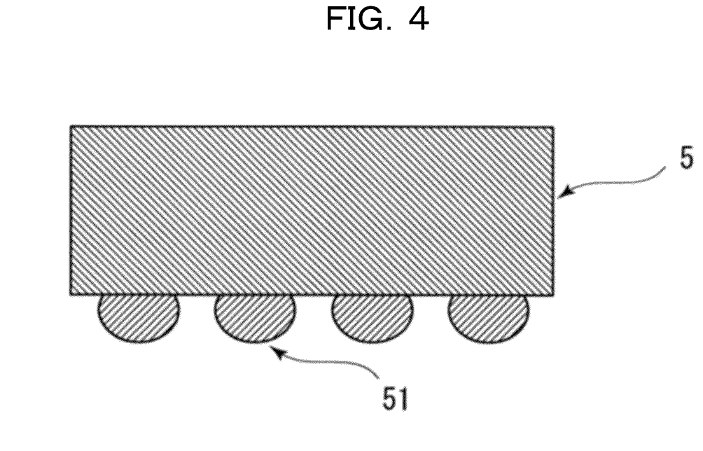

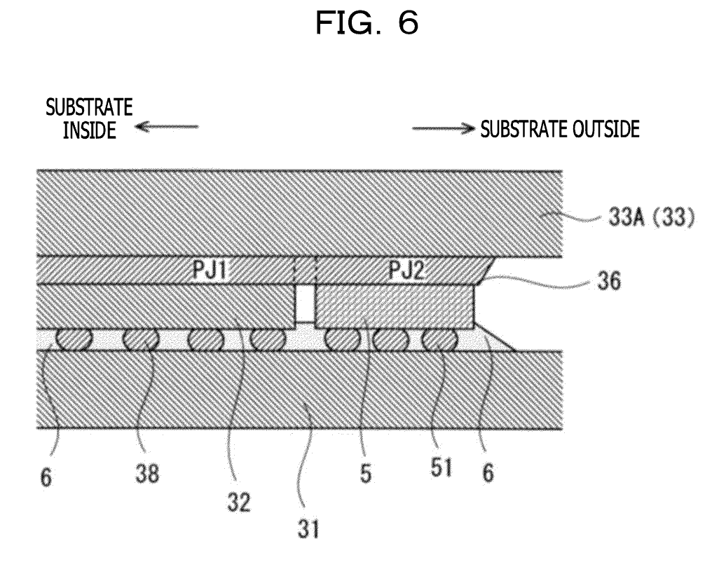

Reference numeral 5 in FIG. 1 indicates stress reducing members provided to reduce the stress generated in the metal joining material 36 located above the semiconductor chip 32. The stress reducing members 5 will now be described in detail with reference to FIGS. 4-6. FIG. 4 is a side view of the stress reducing member 5 according to the present embodiment. FIG. 5 is a plan view illustrating the positioning of the stress reducing members 5 according to the present embodiment. FIG. 6 is a partial cross-sectional view of the semiconductor package 3 according to the present embodiment. More specifically, FIG. 6 mainly illustrates the stress reducing members 5 and the surroundings thereof.

The stress reducing members 5 are formed from the same silicon wafer as the semiconductor chip 32. More specifically, the stress reducing members 5 may be formed by cutting them out of the same silicon wafer as the semiconductor chip 32 in a dicing process in which the semiconductor chip 32 is cut out of the silicon wafer. Since the stress reducing members 5 are cut out of the same silicon wafer as the semiconductor chip 32, the stress reducing members 5 have the same thickness as the semiconductor chip 32. Although each stress reducing member 5 is formed in a square column-like shape having a cross-sectional size of about 0.5 to 2.0 mm (length) by about 0.5 to 2.0 mm (width) in the present embodiment, the stress reducing member 5 is not limited to any specific shape. The size and shape of the stress reducing members 5 are not limited to the above.

Unlike the semiconductor chip 32, the stress reducing members 5 have no inner layer wiring pattern formed therein. A plurality of solder bumps 51 are formed on the lower surface of the stress reducing members 5. Solder bumps 38 similar to those on the stress reducing members 5 are formed on the lower surface of the semiconductor chip 32 as well. The semiconductor chip 32 and stress reducing members 5 are surface-mounted on the package substrate 31. The solder bumps 38, 51 are aligned with the electrodes formed on the package substrate 31 and then the semiconductor chip 32 and stress reducing members 5 are joined to the package substrate 31 in a reflow process (heat treatment), for example. Furthermore, as illustrated in FIG. 6, joining areas between the semiconductor chip 32 and the package substrate 31 and between the stress reducing members 5 and the package substrate 31 are filled with an underfill agent 6. The underfill agent 6 may be epoxy resin or other sealing resin, for example. After the semiconductor chip 32 and stress reducing members 5 are joined to (surface-mounted on) the package substrate 31, the joining areas between the semiconductor chip 32 and the package substrate 31 and between the stress reducing members 5 and the package substrate 31 may be filled and sealed with the underfill agent 6.

The upper surfaces of the stress reducing members 5 are joined to the body section 33A of the heat spreader 33 with the metal joining material 36. More specifically, the metal joining material 36 is applied (supplied) to an area covering not only the upper surface of the semiconductor chip 32 but also the upper surfaces of the stress reducing members 5. As described above, the stress reducing members 5 according to the present embodiment are joined at the lower end (lower surface) thereof to the package substrate 31 and at the upper end (upper surface) thereof to the body section 33A of the heat spreader 33.

Any joining method may be used as long as the stress reducing members 5 are joined at the upper end (upper surface) thereof to the upper surface of the package substrate 31 and at the lower end (lower surface) thereof to the body section 33A of the heat spreader 33. A thermosetting resin adhesive may be used, for example, to join (fasten) the stress reducing members 5 to the package substrate 31 and to the body section 33A of the heat spreader 33.

A joining process will now be described in which the semiconductor chip 32 and the stress reducing members 5 are joined to the heat spreader 33 with the metal joining material 36 and the heat spreader 33 is joined to the package substrate 31 with the thermosetting resin adhesive 37. In this joining process, hot pressing is performed such that the heat spreader 33 and the package substrate 31 are clamped to each other while the semiconductor package 3 is heated until the metal joining material 36 reaches or exceeds the melting point thereof and the thermosetting resin adhesive 37 reaches or exceeds the curing temperature thereof, for example. When the thermosetting resin adhesive 37 cures, the end surface of the leg section 33B of the spreader 33 is joined (bonded) to the surface of the package substrate 31. When the melted metal joining material 36 is cooled and solidified, the semiconductor chip 32 and the heat spreader 33 are mutually joined.

For this hot pressing process, solder as the metal joining material 36 is provided between the lower surface of the body section 33A of the heat spreader 33 and the upper surface of the semiconductor chip 32, for example. Then, the heat spreader 33 and the package substrate 31 are temporarily fixed to each other with the thermosetting resin adhesive 37 applied between the lower surface (end surface) of the leg section 33B of the heat spreader 33 and the upper surface of the package substrate 31. In this state, heat pressing is performed in a vacuum heat press apparatus, for example, under predetermined heating and pressurizing conditions, so the semiconductor chip 32 and the stress reducing members 5 are joined to the heat spreader 33 and the heat spreader 33 is joined to the package substrate 31.

Reference will now be made to a conventional semiconductor package having no stress reducing members 5 provided. In conventional semiconductor packages as well, it is possible to enhance the thermal conductivity between the semiconductor chip and the heat spreader using a metal joining material as the joining material between the semiconductor chip and the heat spreader. Typically, the package substrate and the heat spreader have different coefficients of thermal expansion and the deformability of the cured metal joining material is not so high, so there is a risk that the metal joining material is damaged if stress is concentrated thereon during the manufacture and use of the semiconductor package. First, the concentration of stress on the metal joining material during the manufacture of the semiconductor package will be described. When the members of the semiconductor package shrink in the heat removal stage of the hot pressing process described above, the amounts of shrinkage of the package substrate and the heat spreader differ from each other due to their difference in the coefficient of thermal expansion. For example, the package substrate made of resin shrinks more than the heat spreader made of metal. Such difference in the amount of shrinkage between the heat spreader and package substrate tends to generate stress in the solidified metal joining material.

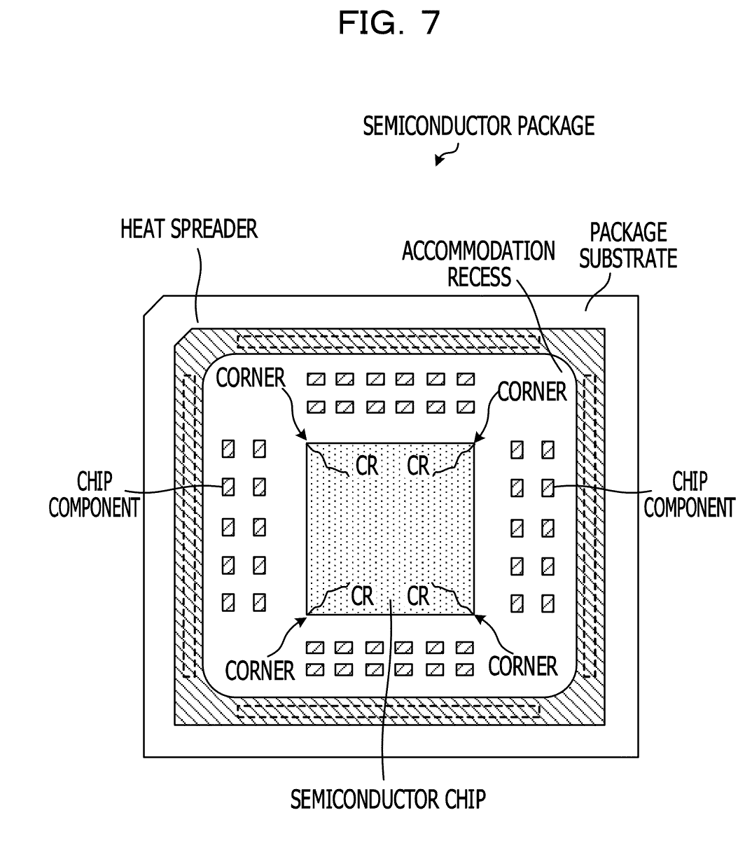

When the semiconductor package built into an electronic device operates, the temperature of the semiconductor chip fluctuates as the semiconductor chip heats and then ceases to heat each time the electronic device is turned on and off. A fastening force is also exerted on the heat spreader by the fastening members when the heat sink is fixedly secured to the main board. This tends to warp the heat spreader and further concentrate stress on the metal joining material. Accordingly, it may be said that, during the manufacture and use of the semiconductor package, the metal joining material joining the semiconductor chip to the heat spreader is under situations where stress is likely to occur. Since the semiconductor chip 32 is substantially rectangular as viewed from above, stress is likely to concentrate on the portions of the metal joining material 36 corresponding to the four corners of the semiconductor chip 32. As a result, as illustrated in FIG. 7 for example, the portions of the metal joining material 36 located on the corners 32A of the semiconductor chip 32 (referred to hereinafter as first joining material portions P31) are likely to be damaged due to cracks and so on (schematically illustrated and denoted with reference character CR in FIG. 7).

In view of this, in the semiconductor package 3 according to the present embodiment, stress reducing members 5 are provided at the positions corresponding to the corners 32A of the semiconductor chip 32 to reduce the stress to be generated in the first joining material portions P31 of the metal joining material 36. The plan-view positioning of the stress reducing members 5 on the package substrate 31 will now be described with reference to FIG. 5. On the package substrate 31, the stress reducing members 5 are disposed at positions corresponding to the corners 32A of the semiconductor chip 32 inside the leg section 33B of the heat spreader 33. Although the stress reducing members 5 are disposed adjacent the four corners of the semiconductor chip 32 in the example illustrated in FIG. 5, the stress reducing members 5 may be disposed at any positions on the lines extended from the diagonal lines of the semiconductor chip 32. In FIG. 5, the areas in which the stress reducing members 5 may be mounted (referred to hereinafter as the mountable areas) are denoted with reference character AP.

Since the stress reducing members 5 are joined at the lower end thereof to the package substrate 31 and at the upper end thereof to the body section 33A of the heat spreader 33 as described above, the upper and lower ends of the stress reducing member 5 are constrained under the same constraint condition as the semiconductor chip 32. By positioning the stress reducing members 5 with their upper and lower ends placed under the same constraint condition as the semiconductor chip 32 in the outer vicinities of the corners 32A of the semiconductor chip 32, the following effect is achieved. It is possible to concentrate stress on the portions of the metal joining material 36 located on the stress reducing members 5 (referred to hereinafter as second joining material portions P32), instead of the first joining material portions P31 of the metal joining material 36 on which stress are likely to concentrate. As a result, it is possible to reduce the stress concentration on the first joining material portions P31 of the metal joining material 36 and thereby suppress damage to the first joining material portions P31. It is possible, therefore, to guarantee the reliability on the quality of the semiconductor package 3 during the manufacture and operation thereof without the risk of reducing the thermal conductivity between the semiconductor chip 32 and the heat spreader 33.

If the stress reducing members 5 are positioned in the mountable areas AP on the package substrate 31, i.e., on the lines extended from the diagonal lines of the semiconductor chip 32, it is possible to reduce effectively the stress concentration on the first joining material portions P31. In the present embodiment, the stress reducing members 5 are disposed at the positions corresponding to the four corners of the semiconductor chip 32, so it is possible to suppress advantageously damage to the first joining material portions P31 located on the corners 32A.

In the semiconductor package 3 in the present embodiment, a layout in which the stress reducing members 5 are disposed at the positions corresponding to the corners 32A of the semiconductor chip 32 on the package substrate 31 is also advantageous for the following reason. When the stress reducing members 5 are disposed in the vicinities of the corners 32A of the semiconductor chip 32 as described above, it is possible to utilize the spaces near the middle of each side (side face) of the semiconductor chip 32 to mount chip components 35. The chip components 35 are electrically connected to the semiconductor chip 32 via a wiring layer formed in the package substrate 31, for example. In the present embodiment, the chip components 35 may be positioned in opposite areas along the sides of the semiconductor chip 32, so it is possible to avoid the wiring layer connecting them from becoming complicated. More specifically, it is possible to shorten the wiring distance in the wiring layer of the package substrate 31 and simplify the conductor pattern forming the wiring layer. Consequently, it is possible to reduce the manufacturing cost of the semiconductor package 3 and improve the reliability of the product.

In the present embodiment, the metal joining material 36 is used to join the upper end (upper surface) of the stress reducing members 5 to the body section 33A of the heat spreader 33, so it is possible to suppress the increase of man hours in the manufacture of the semiconductor package 3. More specifically, in the stage in which solder as the metal joining material 36 is applied between the semiconductor chip 32 and the heat spreader 33, the solder may be applied to an extensive area covering also the upper surfaces of the stress reducing members 5. The use of the metal joining material 36 as the joining material to join the stress reducing members 5 to the heat spreader 33 allows the man hours and thus the manufacturing cost to be reduced in the manufacture of the semiconductor package 3, compared with the case in which a material other than the metal joining material 36 is used. It will be appreciated that a material other than the metal joining material 36 may be used to join the stress reducing members 5 to the heat spreader 33 and damage to the first joining material portions P31 may be suppressed in the same way. As a result, it is possible to suppress the reduction in the efficiency of heat dissipation from the semiconductor chip 32.

Furthermore, in the present embodiment, the stress reducing members 5 are formed from the same material as the semiconductor chip 32. Since the stress reducing members 5 are cut out of the same silicon wafer as the semiconductor chip 32, it is possible to suppress the manufacturing cost of the semiconductor package 3, compared with the case in which the stress reducing members 5 are separately manufactured from scratch. Cutting the stress reducing members 5 out of the same silicon wafer as the semiconductor chip 32 allows the stress reducing members 5 and the semiconductor chip 32 to have the same thickness. Forming the stress reducing members 5 to the same thickness as the semiconductor chip 32 allows the heat spreader 33 and the semiconductor chip 32 to be joined as specified. It will be appreciated that the stress reducing members 5 may be formed from a material different from the semiconductor chip 32 and damage to the first joining material portions P31 may be suppressed in the same way. Consequently, it is possible to suppress the reduction in the efficiency of heat dissipation from the semiconductor chip 32.

In the semiconductor package 3 according to the present embodiment, the joining areas between the semiconductor chip 32 and the package substrate 31 and between the stress reducing members 5 and the package substrate 31 are sealed with the underfill agent 6. With this, it is possible to suppress damage to the joining area between the stress reducing members 5 and the package substrate 31 during the manufacture and operation of the semiconductor package 3. This enables the stress reducing members 5 to fulfill the function of concentrating stress on the second joining material portions P32, instead of the first joining material portions P31. The joining areas between the stress reducing members 5 and the package substrate 31 may be filled with the underfill agent 6 in the stage in which the joining area between the semiconductor chip 32 and the package substrate 31 is filled with the underfill agent 6. More specifically, when the joining area between the semiconductor chip 32 and the package substrate 31 is filled with the underfill agent 6, the underfill agent 6 may further be applied to the joining areas between the stress reducing members 5 and the package substrate 31. This allows the increase of man hours to be suppressed in the manufacture of the semiconductor package 3.

Verification

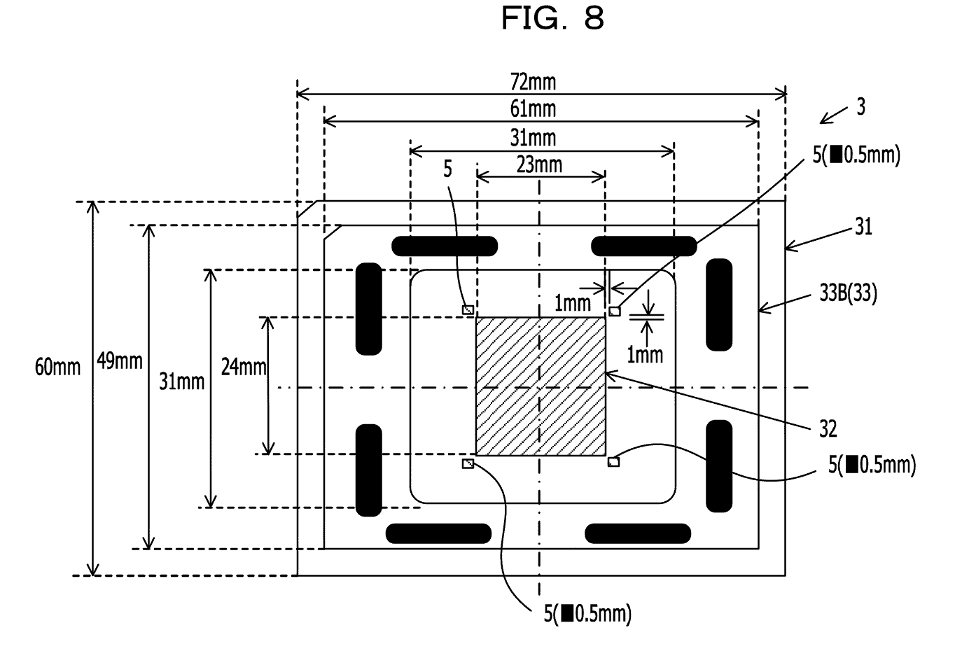

In a semiconductor package 3 according to the embodiment, the effect of reducing the stress exerted on the metal joining material 36 (first joining material portions P31) was verified. The verified semiconductor package 3 will now be described in detail. FIG. 8 is a plan view illustrating the shape and dimensions of the semiconductor package 3 according to the embodiment used in the verification. In the semiconductor package 3 used in the verification, the semiconductor chip 32 had a size of 24 mm (length) by 23 mm (width) and the package substrate 31 had a size of 60 mm (length) by 72 mm (width).

The leg section 33B of the heat spreader 33 had a width of 5.5 mm and was disposed along the outer periphery of the package substrate 31 as illustrated in FIG. 8. The distance between the leg section 33B and each side (side surface) of the semiconductor chip 32 was 3.5 mm in the length direction of the package substrate 31 and 4 mm in the width direction thereof. The stress reducing members 5 had a square cross section of 0.5 mm by 0.5 mm. The distance between the stress reducing members 5 and each side of the semiconductor chip 32 was 1 mm.

In this verification, the semiconductor package 3 according to the embodiment was compared with a semiconductor package according to a comparative example having no stress reducing members 5 provided. The semiconductor package in the comparative example was equivalent to the semiconductor package 3 according to the embodiment except that no stress reducing member was mounted. The verification performed under these conditions yielded the following results. In the comparative example, the metal joining material joining the semiconductor chip to the heat spreader experienced a tensile stress of up to 27.90 MPa and cracked at 100%. On the other hand, in the semiconductor package according to the embodiment, the metal joining material joining the semiconductor chip to the heat spreader experienced a tensile stress of up to 9.27 MPa and did not crack. It was demonstrated that, in the semiconductor package according to the embodiment, the maximum tensile stress exerted on the metal joining material joining the semiconductor chip to the heat spreader was reduced to one third that of the comparative example and no crack occurred.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor package comprising:
a package substrate;
a semiconductor chip mounted on the package substrate;
a heat conductor that has a body section joined to the semiconductor chip via a metal joining material and a leg section that surrounds the semiconductor chip, the leg section extending from the body section to the package substrate and having an end bonded to the package substrate; and
stress reducing members configured to reduce stress exerted on the metal joining material located on the semiconductor chip, the stress reducing members being disposed on the package substrate at positions corresponding to corners of the semiconductor chip inside the leg section and joined to the package substrate and the body section.

2. The semiconductor package according to claim 1, wherein
the stress reducing members are positioned over the package substrate on lines extending from diagonal lines of the semiconductor chip.

3. The semiconductor package according to claim 1, wherein
the stress reducing members are positioned at four corners of the semiconductor chip.

4. The semiconductor package according to claims 1, wherein
the stress reducing members have an upper surface joined to the body section via the metal joining material.

5. The semiconductor package according to claim 1, wherein
the stress reducing members are formed from a same material as the semiconductor chip.

6. The semiconductor package according to claim 1, further comprising;
a joining area between the stress reducing members and
the package substrate is filled with an underfill agent.

7. A wiring board unit comprising:
a semiconductor package that includes
a package substrate,
a semiconductor chip mounted on the package substrate,
a heat conductor that has a body section joined to the semiconductor chip via a metal joining material and a leg section that surrounds the semiconductor chip, the leg section extending from the body section to the package substrate and having an end bonded to the package substrate, and
stress reducing members configured to reduce stress exerted on a metal joining material located on the semiconductor chip, the stress reducing members being disposed on the package substrate at positions corresponding to corners of the semiconductor chip inside the leg section and joined to the package substrate and the body section;
a wiring substrate configured to mount the semiconductor package thereon; and
a cooling member provided on an upper surface of the body section of the heat conductor.
